(19) United States
(12) Patent Application Publication
(10) Pub. No.: US 2022/0069108 A1
(43) Pub. Date: Mar. 3, 2022

(54) Manufacturing Method for Array Substrate and Array Substrate

(71) Applicant: CHENGDU CEC PANDA DISPLAY TECHNOLOGY CO., LTD., Chengdu City, Sichuan (CN)

(72) Inventors: Xiang Liu, Chengdu City, Sichuan (CN); Xuejun SUN, Chengdu City, Sichuan (CN); Guangsheng LI, Chengdu City, Sichuan (CN); Qun MA, Chengdu City, Sichuan (CN)

(73) Assignee: CHENGDU CEC PANDA DISPLAY TECHNOLOGY CO., LTD., Chengdu City, Sichuan (CN)

(21) Appl. No.: 16/758,435

(22) PCT Filed: Mar. 23, 2020
(86) PCT No.: PCT/CN2020/080721

§ 371 Date: Apr. 23, 2020

(30) Foreign Application Priority Data
Oct. 23, 2019 (CN) 201911013988.4

(51) Int. Cl. H01L 29/66; G02F 1/1368; G02F 1/1343; G02F 1/1362; H01L 29/786; G03F 7/20

(52) U.S. Cl. CPC H01L 29/66969; G02F 1/1368; G02F 1/13439; G02F 2202/103; H01L 29/78693; G03F 7/70; G02F 1/136236

(57) ABSTRACT

Provided are a manufacturing method for an array substrate and an array substrate, the method includes: depositing a gate metal layer on a base substrate, and forming a gate electrode by first photolithography process; sequentially depositing a gate insulating layer, a first semiconductor layer, a second semiconductor layer, and a source/drain metal layer, forming an active island, a source electrode, and a drain electrode and forming a channel region between the source electrode and drain electrode by second photolithography process, and converting the second semiconductor layer in channel region into an oxide of silicon; depositing a passivation layer, and forming a conductive via hole on passivation layer over drain electrode by third photolithography process; depositing a transparent conductive layer, and performing fourth photolithography process such that a pixel electrode is formed by transparent conductive layer and that the pixel electrode communicates with the drain electrode through the conductive via hole.

### CROSS-REFERENCE TO RELATED APPLICATIONS

The present disclosure claims priority to Chinese Patent Application No. CN201911013988.4, filed with the Chinese Patent Office on Oct. 23, 2019, entitled “Manufacturing Method for Array Substrate and Array Substrate”, which is incorporated herein by reference in its entirety.

### TECHNICAL FIELD

The present disclosure relates to the technical field of liquid crystal displays, and in particular to a manufacturing method for an array substrate and an array substrate.

### BACKGROUND ART

With the development of display technologies, planar display devices such as liquid crystal displays (referred simply to as LCD) are widely used in various consumer electronics such as mobile phones, TVs, personal digital assistants, and notebook computers and have become dominant display devices, due to their advantages such as high picture quality, power saving, thin body, and no radiation. A liquid crystal display panel generally consists of an array substrate and a color filter substrate disposed opposite to each other, and a liquid crystal molecular layer sandwiched between the array substrate and the color filter substrate. The liquid crystal molecules can be controlled to rotate by applying a driving voltage between the array substrate and the color filter substrate, so that light beams from a backlight module are refracted to generate a picture.

A method of fabricating an array substrate known to the applicant involves six photolithography processes and comprises: a first step of depositing a metal layer on a glass base substrate and performing a first photolithography to form a gate electrode; a second step of sequentially depositing a gate insulating layer and an indium-gallium-zinc oxide (IGZO) semiconductor layer, and performing a second photolithography to form an active island pattern; a third step of depositing an etch stop layer and performing a third photolithography; a fourth step of depositing a source/drain metal layer and performing a fourth photolithography to form a source electrode and a drain electrode; a fifth step of depositing a passivation layer and a planarization layer and performing a fifth photolithography to form a conductive via hole; and a sixth step of depositing a transparent conductive thin film and performing a sixth photolithography to form a pixel electrode and a pattern communicating the conductive via hole with the pixel electrode.

The method for fabricating an array substrate described above involves six photolithography processes, and thus requires a complicated process and high manufacturing cost.

### SUMMARY

The present disclosure provides a manufacturing method for an array substrate and an array substrate. The array substrate can be manufactured with only four photolithography processes, involving a simple process and low manufacturing cost.

An embodiment of the present disclosure provides a manufacturing method for an array substrate, comprising:

depositing a gate metal layer on a base substrate, and forming a gate electrode from the gate metal layer by a first photolithography process;

sequentially depositing a gate insulating layer, a first semiconductor layer, a second semiconductor layer, and a source/drain metal layer, performing a second photolithography process such that an active island is formed by the first semiconductor layer and the second semiconductor layer while a source electrode and a drain electrode are formed by the source/drain metal layer and a channel region is formed between the source electrode and the drain electrode, and then performing an oxidation treatment on the channel region such that the second semiconductor layer located in the channel region is converted into a protective layer;

depositing a passivation layer, and forming a conductive via hole on the passivation layer over the drain electrode by a third photolithography process;

depositing a transparent conductive layer, and performing a fourth photolithography process such that a pixel electrode is formed by the transparent conductive layer and that the pixel electrode communicates with the drain electrode through the conductive via hole.

Optionally, the second photolithography process comprises a gray-tone mask process or a half-tone mask process.

Optionally, the second photolithography process specifically comprises:

performing exposure and development using a mask to form a completely transmissive area, a partially transmissive area, and an opaque area, the opaque area corresponding to the source electrode and the drain electrode, the partially transmissive area corresponding to the channel region;

performing a first etching to etch away the source/drain metal layer, the second semiconductor layer, and the first semiconductor layer which are corresponding to the completely transmissive area;

performing a photoresist ashing process to remove a photoresist from the partially transmissive area; performing a second etching to etch away the source/drain metal layer in the partially transmissive area to form the channel region;

retaining the source/drain metal layer corresponding to the opaque area to form the source electrode and the drain electrode.

Optionally, the first semiconductor layer is a metal oxide semiconductor layer, including an amorphous indium-gallium-zinc oxide (a-IGZO).

Optionally, in the deposition of the first semiconductor layer, the content of oxygen in the metal oxide semiconductor layer is reduced to reduce the conductivity of the first semiconductor layer.

Optionally, the second semiconductor layer is a heavily doped amorphous silicon semiconductor layer.

Optionally, the protective layer is an oxide of silicon.

Optionally, the first semiconductor layer is deposited and formed by a sputtering method, and the second semiconductor layer is deposited and formed by a plasma-enhanced chemical vapor deposition method.

Optionally, the first semiconductor layer has a thickness of 50 to 2000 Å, and the second semiconductor layer has a thickness of 50 to 500 Å.

In the manufacturing method for an array substrate according to the embodiment of the present disclosure, a metal oxide thin film transistor structure is used. A metal oxide semiconductor layer pattern, source and drain metal electrodes, data and scan lines, and a channel region between the source electrode and the drain electrode are formed simultaneously by using one half-tone or gray-tone mask in the second photolithography process, and the heavily doped amorphous silicon semiconductor layer in the channel region is subjected to an oxidation treatment such that it is converted into an oxide of silicon. Thus, two photolithography process are omitted, and the production efficiency is improved. Moreover, a double-layered semiconductor layer structure is ingeniously designed. The upper layer is a heavily doped amorphous silicon semiconductor layer. The amorphous silicon semiconductor layer is in direct contact with the source and drain metal electrodes, whereby the contact resistance between the source and drain metal electrodes and the semiconductor layer can be reduced, and the lower metal oxide semiconductor layer can be protected from corrosion in the formation of the source and drain metal electrodes. Such a design reduces the process difficulty and improves the performance and stability of the thin film transistor.

An embodiment of the present disclosure further provides an array substrate, which is manufactured by the manufacturing method described above, wherein the array substrate comprises a base substrate, and a gate electrode, a gate insulating layer, a first semiconductor layer, a second semiconductor layer, a source/drain layer, a passivation layer, and a pixel electrode sequentially disposed on the base substrate, the source/drain layer comprises a source electrode and a drain electrode, and a channel region is provided between the source electrode and the drain electrode;

the first semiconductor layer is a metal oxide semiconductor layer, and the second semiconductor layer is a heavily doped amorphous silicon semiconductor layer; a protective layer is provided in the channel region, and the protective layer is an oxide of silicon formed by performing an oxidation treatment on the second semiconductor layer;

the passivation layer has a conductive via hole through which the pixel electrode communicates with the drain electrode.

In the array substrate according to the embodiment of the present disclosure, a double-layered semiconductor layer structure is used. The upper layer is a heavily doped amorphous semiconductor layer, the lower layer is a metal oxide semiconductor layer with low oxygen content, and the upper amorphous semiconductor layer is in direct contact with the source and drain metal electrodes, whereby the contact resistance between the source and drain metal electrodes and the semiconductor layer is reduced, and the lower metal oxide semiconductor layer can be protected from corrosion. Moreover, the amorphous silicon in the channel region is converted into an oxide of silicon by using a process of oxidation of the heavily doped amorphous silicon. On the other hand, in the deposition of the lower metal oxide semiconductor layer, the oxygen content is controlled during the deposition so that the lower metal oxide semiconductor layer has a low oxygen content and thus has low conductivity, thereby improving the performance and stability of the thin film transistor. Such a design allows the metal oxide semiconductor layer, the source and drain metal electrodes, the data line, and the channel region to be formed in the same photolithography process. In this way, two photolithography processes are omitted, and also the formation of an etch stop layer is avoided, whereby the difficulty in the fabrication process is reduced.

### BRIEF DESCRIPTION OF DRAWINGS

In order to more clearly illustrate technical solutions of the present disclosure or of the prior art, drawings required for use in the description of the embodiments or the prior art will be described briefly below. It is obvious that the drawings in the following description are illustrative of some embodiments of the present disclosure. It will be understood by those of ordinary skill in the art that other drawings can also be obtained from these drawings without any inventive effort.

FIG. 1 is a plan view of an array substrate according to an embodiment of the present disclosure;

FIG. 2 is a flowchart of a manufacturing method for an array substrate according to an embodiment of the present disclosure;

FIG. 3 is a schematic structural view of an array substrate along a direction AB obtained after a first photolithography process is completed according to an embodiment of the present disclosure;

FIG. 4 is a schematic structural view of the array substrate along the direction AB obtained after exposure and development in a second photolithography process are completed according to the embodiment of the present disclosure;

FIG. 5 is a schematic structural view of the array substrate along the direction AB obtained after a first etching in the second photolithography process is completed according to the embodiment of the present disclosure;

FIG. 6 is a schematic structural view of the array substrate along the direction AB obtained after ashing in the second photolithography process is completed according to the embodiment of the present disclosure;

FIG. 7 is a schematic structural view of the array substrate along the direction AB obtained after the second photolithography process is completed according to the embodiment of the present disclosure;

FIG. 8 is a schematic structural view of the array substrate along the direction AB obtained after a third photolithography process is completed according to the embodiment of the present disclosure; and

FIG. 9 is a schematic structural view of the array substrate along the direction AB obtained after a fourth photolithography process is completed according to the embodiment of the present disclosure.

### REFERENCE NUMERALS

11—base substrate;
12—gate electrode;
13—gate insulating layer;
14—first semiconductor layer;
15—second semiconductor layer;
151—protective layer;
16—source/drain metal layer;
161—source electrode;
162—drain electrode;
17—photoresist;
18—completely transmissive area;
19—opaque area;
20—partially transmissive area;
21—channel region;
22—passivation layer;
23—conductive via hole;
24—pixel electrode;
25—scan line;
26—data line.

### DETAILED DESCRIPTION OF EMBODIMENTS

In order to further clarify the objects, technical solutions, and advantages of the present disclosure, the technical solutions of the present disclosure will be described below clearly and completely with reference to the accompanying drawings of the present disclosure. It is apparent that the embodiments to be described are some, but not all of the embodiments of the present disclosure. All the other embodiments obtained by those of ordinary skill in the art in light of the embodiments of the present disclosure without inventive efforts will fall within the scope of the present disclosure as claimed.

It should be understood that the traditional liquid crystal display panel is formed by attaching a thin film transistor array substrate (referred simply to as TFT array substrate) to a color filter substrate (referred simply to as CF substrate), wherein a pixel electrode and a common electrode are formed on the array substrate and the color filter substrate, respectively, and liquid crystals are poured between the array substrate and the color filter substrate. It is operated based on the principle that a rotation of the liquid crystal molecules in the liquid crystal layer is controlled using an electric field generated between the pixel electrode and the common electrode by applying a driving voltage between the pixel electrode and the common electrode, so that light beams from a backlight module are refracted to generate a picture.

A mask, also called a photo mask, is a pattern master used in a photolithography process. That is, a mask pattern is formed on a transparent base substrate by an opaque light-shielding thin film (of metal chromium), and the pattern is transferred onto a thin film of a glass base substrate by a photolithography process. An exposure procedure is a procedure in which a photoresist is irradiated with ultraviolet light through a mask, so that a pattern on the mask is transferred onto the photoresist. In the array process, the photoresist functions as a mask. In an etching process, a thin film layer of the substrate corresponding to the photoresist pattern formed by exposure is retained and other areas are etched. Finally, the photoresist is removed, and the pattern on the mask is transferred onto the substrate. This procedure is called photolithography. Each photolithography process involves several process steps of deposition of thin films, application of a photoresist, exposure, development, etching, and stripping of the photoresist.

It can be understood that the number of photolithography process steps affects both the productivity of panels and the fabrication cost of the panels. Therefore, the photolithography processes should be performed as few times as possible.

The present disclosure will be described below with reference to the accompanying drawings in connection with specific embodiments.

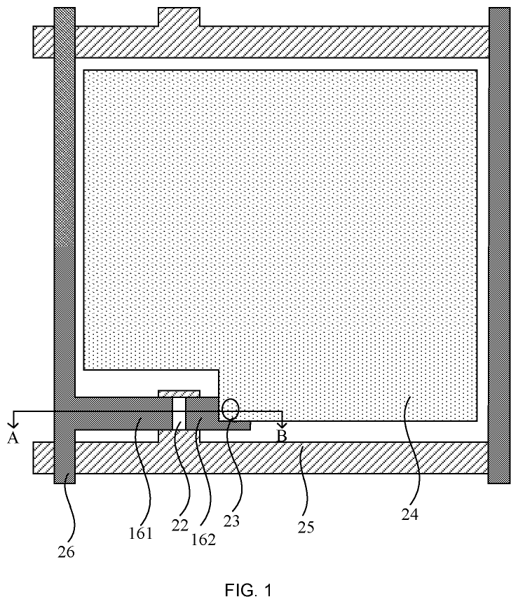

FIG. 1 is a plan view of an array substrate according to an embodiment of the present disclosure. Referring to FIG. 1, an array substrate according to an embodiment of the present disclosure may comprise a source electrode 161, a drain electrode 162, a passivation layer 22, a conductive via hole 23, a pixel electrode 24, a scan line 25, and a data line 26, wherein the pixel electrode 24 may communicate with the drain electrode 162 via the conductive via hole 23, the scan line 25 may communicate with the gate electrode 12 and both of them may be formed in the same photolithography process, and the data line 26 may communicate with the source electrode 161 and both of them may be formed in the same photolithography process. It should be noted that FIG. 1 is a plan view of the array substrate. Part of the structure of the array substrate is not shown in FIG. 1 due to the angle of view, and therefore is not described here.

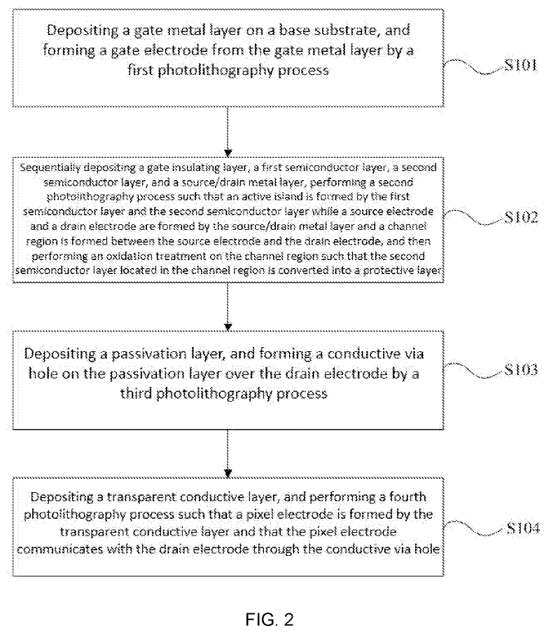

FIG. 2 is a flowchart of a manufacturing method for an array substrate according to an embodiment of the present disclosure. As shown in FIG. 2, a manufacturing method for an array substrate according to an embodiment of the present disclosure may comprise S101 to S104.

In S101, a gate metal layer is deposited on a base substrate 11, and a gate electrode 12 is formed from the gate metal layer by a first photolithography process.

Specifically, a gate metal layer having a thickness of about 500 to 4000 Å is deposited on the base substrate 11 by using a sputtering or thermal evaporation method. The gate metal layer may be made of a material selected from metals such as Cr, W, Ti, Ta, Mo, Al, and Cu, or an alloy thereof, and a gate metal layer consisting of a plurality of metal layers can also meet the requirements. FIG. 3 is a schematic structural view of an array substrate along a direction AB obtained after the first photolithography process is completed according to an embodiment of the present disclosure. As shown in FIG. 3, a gate electrode 12 is formed from the gate metal layer by the first photolithography process.

In S102, a gate insulating layer 13, a first semiconductor layer 14, a second semiconductor layer 15, and a source/drain metal layer 16 are sequentially deposited, a second photolithography process is performed such that an active island is formed by the first semiconductor layer 14 and the second semiconductor layer 15 while a source electrode 161 and a drain electrode 162 are formed by the source/drain metal layer 16 and a channel region 21 is formed between the source electrode 161 and the drain electrode 162, and then the channel region 21 is subjected to an oxidation treatment such that the second semiconductor layer 15 in the channel region 21 is converted into a protective layer.

Specifically, a gate insulating layer 13 having a thickness of 2000 to 5000 Å is continuously deposited by a plasma-enhanced chemical vapor deposition (PECVD) method on the base substrate 11 which has been subjected to the step S101. The gate insulating layer 13 may be made of a material selected from an oxide, a nitride, or an oxynitride, and the corresponding reaction gas may be SiH₄, NH₃ or N₂ or SiH₂Cl₂, NH₃ or N₂.

Then, a first semiconductor layer 14 having a thickness of 50 to 2000 Å is continuously deposited by a sputtering method. The first semiconductor layer 14 is a layer of a metal oxide semiconductor, which may be an amorphous oxide semiconductor or a polycrystalline oxide semiconductor, which may, for example, be made of a material selected from an amorphous indium-gallium-zinc oxide (a-IGZO), HIZO, IZO, a-InZnO, ZnO:F, In₂O₃:Sn, In₂O₃:Mo, Cd₂SnO₄, ZnO:Al, TiO₂:Nb, Cd—Sn—O, or other metal oxides, and which may be provided as a single layer or multiple layers.

In the deposition of the metal oxide semiconductor layer, the conductivity of the metal oxide semiconductor can be effectively controlled by controlling the oxygen content in the metal oxide semiconductor. If the oxygen content is higher in a deposited metal oxide semiconductor layer thin film, the metal oxide semiconductor thin film has better conductivity which is more approximate to that of a conductor. If the oxygen content is lower in a deposited metal oxide semiconductor layer thin film, the metal oxide semiconductor thin film has worse conductivity which is more approximate to that of a semiconductor. The metal oxide semiconductor layer 14 in the embodiment of the present disclosure has a low oxygen content and therefore has low conductivity. The metal oxide semiconductor layer 14 is in direct contact with the gate insulating layer 13. A channel region 21 is formed by the metal oxide semiconductor layer 14 between the source electrode 161 and the drain electrode 162. A semiconductor thin film transistor formed by the metal oxide semiconductor layer 14 with low oxygen content has more stable performance.

Then, a second semiconductor layer 15 having a thickness of 50 to 500 Å is continuously deposited by the PECVD method. The second semiconductor layer 15 is a heavily doped amorphous silicon semiconductor layer. Here, doping refers to the addition of a conductive element in a tetravalent semiconductor. For example, trivalent boron or pentavalent phosphorus or the like is added to silicon or germanium to improve the conductivity of the semiconductor. The larger the proportion of the conductive element added, the stronger conductivity the semiconductor has. In general, the conductive element is added in the order of one millionth (ppm). The doping may be divided into light doping, medium doping, and heavy doping depending on different proportions of the conductive elements added. For example, doping of 5 ppm or less is light doping, doping of 5 to 20 ppm (inclusive of 5 and exclusive of 20) is medium doping, and doping of 20 ppm or more is heavy doping. The heavily doped amorphous silicon semiconductor layer is a semiconductor layer with high conductivity, which is in direct contact with the source and drain metal electrodes. In this way, a contact resistance between the semiconductor layer and the source and drain metal electrodes can be reduced, and the on-state current of the thin film transistor can be increased.

Next, a source/drain metal layer 16 having a thickness of 2000 to 4000 Å is deposited by sputtering or thermal evaporation. The source/drain metal layer 16 may be selected from a metal such as Cr, W, Ti, Ta, or Mo, and an alloy thereof, and may be provided as a single layer or multiple layers.

Specifically, the second photolithography is performed by a half-tone mask process or a gray-tone mask process. Here, the half-tone mask (referred simply to as HTM) process is a process in which the photoresist is incompletely exposed to light by using a semi-transmissive film on a mask. The gray-tone mask process is a process in which the photoresist is incompletely exposed to light by using light-blocking strips in a gray-scale area on a mask.

The second photolithography process may specifically comprise the following procedures:

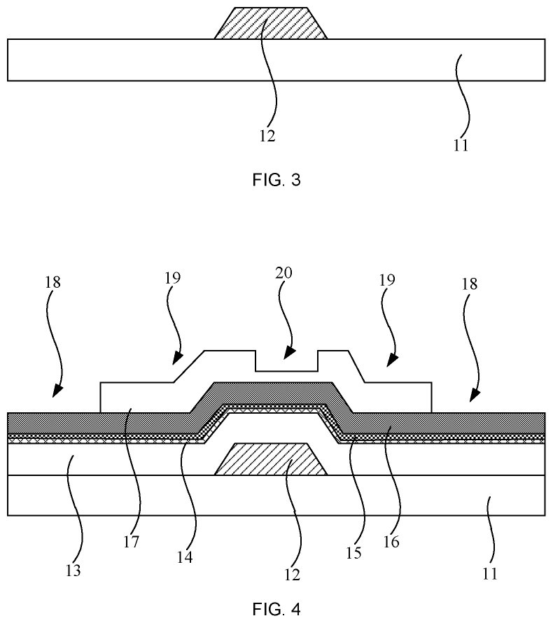

Exposure and development are performed using a mask. As shown in FIG. 4 which is a structural schematic view of the array substrate along the direction AB obtained after exposure and development in the second photolithography process are performed according to the embodiment of the present disclosure, a completely transmissive area 18, an opaque area 19, and a partially transmissive area 20 are formed. The opaque area 19 corresponds to a source electrode, a drain electrode, and a data line 26, the partially transmissive area 20 corresponds to the channel region 21 between the source electrode and the drain electrode, and the completely transmissive area 18 corresponds to areas other than the opaque area 19 and the partially transmissive area 20. The partially transmissive area 20 is located between the two opaque areas 19, and the two completely transmissive areas 18 are located on the two sides of the two opaque areas 19, respectively.

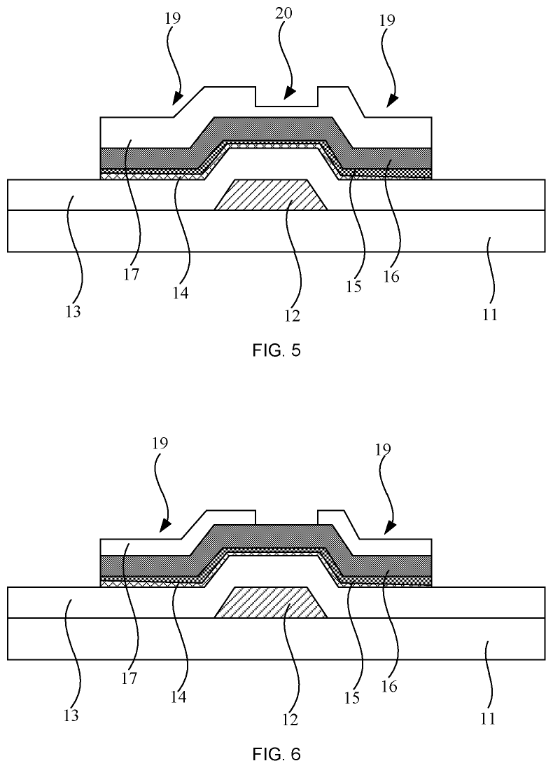

Next, a first etching is performed. As shown in FIG. 5 which is a structural schematic view of the array substrate along the direction AB obtained after the first etching in the second photolithography process is performed according to the embodiment of the present disclosure, the source/drain metal layer 16, the second semiconductor layer 15, and the first semiconductor layer 14 are removed from the completely transmissive areas 18 by the etching process, so that only the gate insulating layer 13 and the portion underneath it are retained in the completely transmissive areas 18. After the etching is completed, an active island is formed by the first semiconductor layer 14 and the second semiconductor layer 15, the source/drain metal layer 16 over the active island is retained, and the first semiconductor layer 14, the second semiconductor layer 15, and the source/drain metal layer other than the active island are all etched away.

Next, a photoresist ashing process is performed. As shown in FIG. 6 which is a structural schematic view of the array substrate along the direction AB obtained after ashing in the second photolithography process is performed according to the embodiment of the present disclosure, a photoresist 17 in the partially transmissive area 20 is removed.

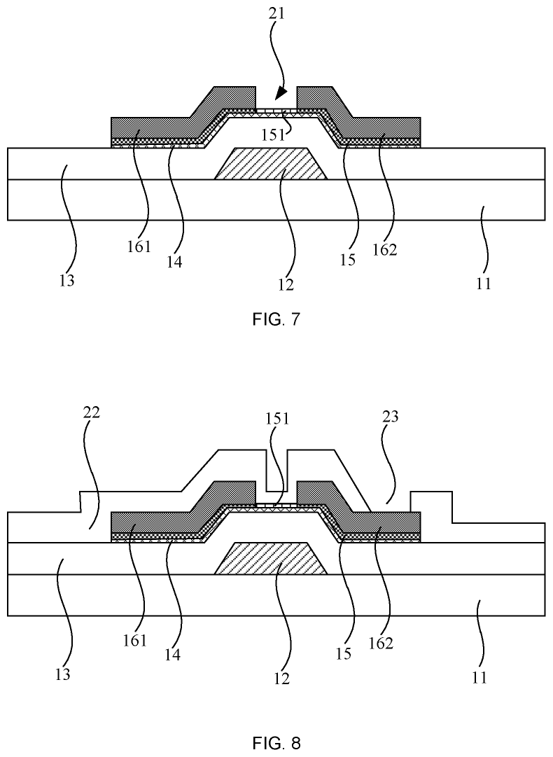

Next, a second etching is performed. As shown in FIG. 7 which is a structural schematic view of the array substrate along the direction AB obtained after the second photolithography process is performed according to the embodiment of the present disclosure, the source/drain metal layer 16 in the partially transmissive area 20 is etched by the etching process so as to form a channel region 21 between the source electrode and the drain electrode. The unetched source/drain metal layer 16 on the left side forms the source electrode 161, and the unetched source/drain metal layer 16 on the right side forms the drain electrode 162.

Next, the second semiconductor layer 15 in the channel region 21 is subjected to an oxidation treatment. The oxidation treatment may be performed in an oxygen plasma environment in a dry etching device, at a RF power of 5 KW to 10 KW at an air pressure of 200 mT to 600 mT at a gas flow rate of 1000 to 4000 sccm. After the oxidation treatment is performed, the heavily doped amorphous silicon semiconductor layer in the channel region 21 is converted into an oxide of silicon. The oxide of silicon is the protective layer 151.

In S103, a passivation layer 22 is deposited, and a conductive via hole 23 is formed in the passivation layer 22 over the drain electrode 162 by a third photolithography process.

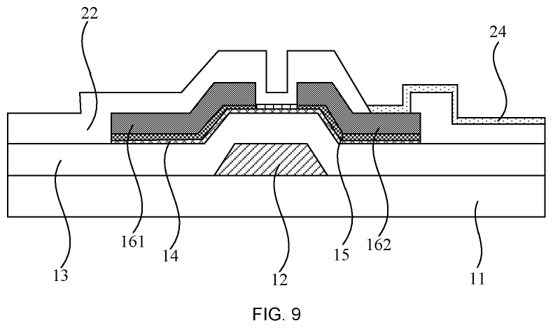

FIG. 8 is a structural schematic view of the array substrate along the direction AB obtained after the third photolithography process is completed according to the embodiment of the present disclosure. As shown in FIG. 8, specifically, a passivation layer 22 having a thickness of 2000 to 5000 Å is continuously deposited by the plasma-enhanced chemical vapor deposition method on the base substrate 11 which has been subjected to the step S102. The passivation layer 22 may be made of a material selected from an oxide, a nitride, or an oxynitride and may be provided as a single layer or multiple layers, and the corresponding reaction gas may be SiH₄, NH₃ or N₂ or SiH₂Cl₂, NH₃ or N₂. A passivation layer pattern having a conductive via hole 23 is formed by the third photolithography process. The conductive via hole 23 is located over the drain electrode 162.

In S104, a transparent conductive layer is deposited, and a fourth photolithography process is performed such that a pixel electrode 24 is formed by the transparent conductive layer and that the pixel electrode 24 communicates with the drain electrode 162 through the conductive via hole 23.

FIG. 9 is a structural schematic view of the array substrate along the direction AB obtained after the fourth photolithography process is completed according to the embodiment of the present disclosure. As shown in FIG. 9, specifically, a transparent conductive layer having a thickness of about 300 to 1500 Å is continuously deposited by the sputtering or thermal evaporation method on the base substrate 11 which has been subjected to the step S103. The transparent conductive layer may be made of an indium tin oxide (ITO) or an indium zinc oxide (IZO), or any other transparent metal oxide. The fourth photolithography process is performed such that a pixel electrode 24 is formed by the transparent conductive layer and that the pixel electrode 24 communicates with the drain electrode 162 through the conductive via hole 23.

In the manufacturing method for an array substrate according to the embodiment of the present disclosure, a metal oxide thin film transistor structure is used. A metal oxide semiconductor layer pattern, source and drain metal electrodes, data and scan lines, and a channel region between the source electrode and the drain electrode are formed simultaneously by using one half-tone or gray-tone mask in the second photolithography process, and the heavily doped amorphous silicon semiconductor layer in the channel region is subjected to an oxidation treatment such that it is converted into an oxide of silicon. Thus, two photolithography process are omitted, and the production efficiency is improved. Moreover, a double-layered semiconductor layer structure is ingeniously designed. The upper layer is a heavily doped amorphous silicon semiconductor layer. The amorphous silicon semiconductor layer is in direct contact with the source and drain metal electrodes, whereby the contact resistance between the source and drain metal electrodes and the semiconductor layer can be reduced, and the lower metal oxide semiconductor layer can be protected from corrosion in the formation of the source and drain metal electrodes. Such a design reduces the process difficulty and improves the performance and stability of the thin film transistor.

An embodiment of the present disclosure further provides an array substrate. The array substrate is manufactured by the method described above. As shown in FIG. 1 and FIG. 9, the array substrate may comprise: a base substrate 11, and a gate electrode 12, a gate insulating layer 13, a first semiconductor layer 14, a second semiconductor layer 15, a source/drain layer, a passivation layer 22, and a pixel electrode 24 sequentially disposed on the base substrate 11, the source/drain layer may comprise a source electrode 161 and a drain electrode 162, and a channel region 21 may be provided between the source electrode 161 and the drain electrode 162; wherein the first semiconductor layer 14 is a metal oxide semiconductor layer, the second semiconductor layer 15 is a heavily doped amorphous silicon semiconductor layer, a protective layer 151 is provided in the channel region 21, and the protective layer 151 is an oxide of silicon formed by performing an oxidation treatment on the second semiconductor layer 15; the passivation layer 22 has a conductive via hole 23, and the pixel electrode 24 communicates with the drain electrode 162 through the conductive via hole 23.

The array substrate may further comprise a scan line 25 and a data line 26. The scan line 25 may communicate with the gate electrode 12 and both of them are formed in the same photolithography process. The data line 26 may communicate with the source electrode 161 and both of them may be formed in the same photolithography process.

Here, the gate electrode 12 may have a thickness of about 500 to 4000 Å, and the gate electrode may be made of a material selected from metals such as Cr, W, Ti, Ta, Mo, Al, and Cu, or an alloy thereof. A gate metal layer consisting of a plurality of metal layers can also meet the requirements.

The gate insulating layer 13 may have a thickness of 2000 to 5000 Å, and the gate insulating layer may be made of a material selected from an oxide, a nitride, and an oxynitride. The corresponding reaction gas may be SiH₄, NH₃ or N₂ or SiH₂Cl₂, NH₃ or N₂.

The first semiconductor layer 14 may have a thickness of 50 to 2000 Å. The second semiconductor 15 may have a thickness of 50 to 2000 Å. The first semiconductor layer 14 may be a metal oxide semiconductor, which may be an amorphous oxide semiconductor or a polycrystalline oxide semiconductor, which may, for example, be made of a material selected from an amorphous indium-gallium-zinc oxide (a-IGZO), HIZO, IZO, a-InZnO, ZnO:F, In₂O₃:Sn, In₂O₃:Mo, Cd₂SnO₄, ZnO:Al, TiO₂:Nb, Cd—Sn—O, or other metal oxides. The metal oxide semiconductor layer 14 has a low oxygen content and therefore has low conductivity. The metal oxide semiconductor layer 14 is in direct contact with the gate insulating layer 13. A channel region 21 is formed by the metal oxide semiconductor layer 14 between the source electrode 161 and the drain electrode 162 of the thin film transistor. A semiconductor thin film transistor formed by the metal oxide semiconductor layer with low oxygen content has more stable performance.

The second semiconductor layer 15 may be a heavily doped amorphous silicon semiconductor. The heavily doped amorphous silicon semiconductor layer is a semiconductor layer with high conductivity, which is in direct contact with the source and drain metal electrodes. In this way, a contact resistance between the semiconductor layer and the source and drain metal electrodes can be reduced, and the on-state current of the thin film transistor can be increased.

The source/drain metal layer 16 may have a thickness of 2000 to 4000 Å, may be selected from a metal such as Cr, W, Ti, Ta, or Mo and an alloy thereof, and may be provided as a single layer or multiple layers.

The passivation layer 22 may have a thickness of 2000 to 5000 Å. The passivation layer may be made of a material selected from an oxide, a nitride, or an oxynitride and may be provided as a single layer or multiple layers. The corresponding reaction gas may be SiH₄, NH₃ or N₂ or SiH₂Cl₂, NH₃ or N₂.

In the array substrate according to the embodiment of the present disclosure, a double-layered semiconductor layer structure is used. The upper layer is a heavily doped amorphous semiconductor layer, the lower layer is a metal oxide semiconductor layer with low oxygen content, and the upper amorphous semiconductor layer is in direct contact with the source and drain metal electrodes, whereby the contact resistance between the source and drain metal electrodes and the semiconductor layer is reduced, and the lower metal oxide semiconductor layer can be protected from corrosion. Moreover, the amorphous silicon in the channel region is converted into an oxide of silicon by using a process of oxidation of the heavily doped amorphous silicon. On the other hand, in the deposition of the lower metal oxide semiconductor layer, the oxygen content is controlled during the deposition so that the lower metal oxide semiconductor layer has a low oxygen content and thus has low conductivity, thereby improving the performance and stability of the thin film transistor. Such a design allows the metal oxide semiconductor layer, the source and drain metal electrodes, the data line, and the channel region to be formed in the same photolithography process. In this way, two photolithography processes are omitted, and also the formation of an etch stop layer is avoided, whereby the difficulty in the fabrication process is reduced.

In the description of the present disclosure, it should be understood that orientation or positional relationships indicated by the terms used herein such as “center”, “length”, “width”, “thickness”, “top end”, “bottom end”, “up”, “down”, “left”, “right”, “front”, “rear”, “vertical”, “horizontal”, “inside”, “outside”, “axial direction”, and “circumferential direction” are the orientation or positional relationships shown based on the figures, and these terms are intended only to facilitate the description of the present disclosure and simplify the description, but not intended to indicate or imply that the referred devices or elements must be in a particular orientation or constructed or operated in the particular orientation, and therefore should not be construed as limiting the present disclosure.

In addition, the term “first” or “second” is used for descriptive purpose only, and should not be understood as an indication or implication of relative importance or an implicit indication of the number of the indicated technical features. Therefore, a feature defined with the term “first” or “second” may explicitly or implicitly include one or more such features. In the description of the present disclosure, “a plurality” means at least two, for example two or three or more, unless otherwise expressly and specifically defined.

In the present disclosure, the term “mounted”, “coupled”, “connected”, “fixed”, or the like should be understood broadly unless otherwise expressly specified or defined. For example, connection may be fixed connection or detachable connection or integral connection, may be mechanical connection or electric connection or mutual communication, or may be direct coupling or indirect coupling via an intermediate medium or internal communication between two elements or interaction between two elements. The specific meanings of the above-mentioned terms in the present disclosure can be understood by those of ordinary skill in the art according to specific situations.

In the present application, unless otherwise expressly specified or defined, a first feature “on” (or above) or “below” a second feature may include a case where the first and second features are in direct contact, and may also include a case where the first and second features are not in direct contact, but are in contact via an additional feature therebetween. Moreover, a first feature “on”, “above”, or “over” a second feature is meant to include a case where the first feature is directly above or obliquely above the second feature, or merely means that the first feature is at a level height higher than the second feature. A first feature “below”, “under”, or “underneath” a second feature is meant to include a case where the first feature is directly below or obliquely below the second feature, or merely means that the first feature is at a level height lower than the second feature.

Finally, it should be noted that the above embodiments are merely intended to illustrate the technical solutions of the present disclosure, but not intended to limit the present disclosure. Although the present disclosure has been described in detail with reference to the foregoing embodiments, it should be understood by those of ordinary skill in the art that the technical solutions disclosed in the foregoing embodiments may still be modified, or some or all of the technical features thereof may be replaced with equivalents; and such modifications or replacements will not cause the essence of the corresponding technical solutions to depart from the scope of the technical solutions of the embodiments of the present disclosure.

### INDUSTRIAL APPLICABILITY

In a manufacturing method for an array substrate and an array substrate manufactured by the method according to the embodiments of the present disclosure, a metal oxide thin film transistor structure is used. A metal oxide semiconductor layer pattern, source and drain metal electrodes, data and scan lines, and a channel region between the source electrode and the drain electrode are formed simultaneously by using one half-tone or gray-tone mask in the second photolithography process. That is to say, the metal oxide semiconductor layer, the source and drain metal electrodes, the data line, and the channel region are formed in the same photolithography process. In this way, two photolithography processes are omitted, and also the formation of an etch stop layer is avoided, whereby the difficulty in the fabrication process is reduced. In addition, the heavily doped amorphous silicon semiconductor layer in the channel region is subjected to an oxidation treatment such that it is converted into an oxide of silicon. Moreover, a double-layered semiconductor layer structure is ingeniously designed. The upper layer is a heavily doped amorphous silicon semiconductor layer. The amorphous silicon semiconductor layer is in direct contact with the source and drain metal electrodes, whereby the contact resistance between the source and drain metal electrodes and the semiconductor layer can be reduced, and the lower metal oxide semiconductor layer can be protected from corrosion in the formation of the source and drain metal electrodes. Such a design reduces the process difficulty. On the other hand, in the deposition of the lower metal oxide semiconductor layer, the oxygen content is controlled during the deposition so that the lower metal oxide semiconductor layer has a low oxygen content and thus has low conductivity, thereby improving the performance and stability of the thin film transistor.

1. A manufacturing method for an array substrate, comprising:
depositing a gate metal layer on a base substrate, and forming a gate electrode from the gate metal layer by a first photolithography process;
sequentially depositing a gate insulating layer, a first semiconductor layer, a second semiconductor layer, and a source/drain metal layer on the base substrate on which the gate electrode is formed, performing a second photolithography process such that an active island is formed by the first semiconductor layer and the second semiconductor layer while a source electrode and a drain electrode are formed by the source/drain metal layer and a channel region is formed between the source electrode and the drain electrode, and then performing an oxidation treatment on the channel region such that the second semiconductor layer located in the channel region is converted into a protective layer;
depositing a passivation layer, and forming a conductive via hole on the passivation layer over the drain electrode by a third photolithography process; and
depositing a transparent conductive layer, and performing a fourth photolithography process such that a pixel electrode is formed by the transparent conductive layer and that the pixel electrode communicates with the drain electrode through the conductive via hole.

2. The manufacturing method according to claim 1, wherein the second photolithography process comprises a gray-tone mask process or a half-tone mask process.

3. The manufacturing method according to claim 2, wherein the second photolithography process comprises:
performing exposure and development using a mask to form a completely transmissive area, a partially transmissive area, and an opaque area, wherein the opaque area corresponds to the source electrode and the drain electrode and the partially transmissive area corresponds to the channel region;
performing a first etching to etch away the source/drain metal layer corresponding to the completely transmissive area, the second semiconductor layer corresponding to the completely transmissive area, and the first semiconductor layer corresponding to the completely transmissive area;
performing a photoresist asking process to remove a photoresist from the partially transmissive area; performing a second etching to etch away the source/drain metal layer in the partially transmissive area to form the channel region; and
retaining the source/drain metal layer corresponding to the opaque area to form the source electrode and the drain electrode.

4. The manufacturing method according to claim 1, wherein the first semiconductor layer is a metal oxide semiconductor layer, comprising an amorphous indium-gallium-zinc oxide a-IGZO.

5. The manufacturing method according to claim 4, wherein when depositing the first semiconductor layer, a content of oxygen in the metal oxide semiconductor layer is reduced to reduce a conductivity of the first semiconductor layer.

6. The manufacturing method according to claim 1, wherein the second semiconductor layer is a heavily doped amorphous silicon semiconductor layer.

7. The manufacturing method according to claim 6, wherein the protective layer is an oxide of silicon.

8. The manufacturing method according to claim 1, wherein the first semiconductor layer is formed by depositing by a sputtering method, and the second semiconductor layer is formed by depositing by a plasma-enhanced chemical vapor deposition method.

9. The manufacturing method according to claim 1, wherein the first semiconductor layer has a thickness of 50 to 2000 Å, and the second semiconductor layer has a thickness of 50 to 500 Å.

10. The manufacturing method according to claim 1, wherein the oxidation treatment is performed in an oxygen plasma environment in a dry etching device.

11. The manufacturing method according to claim 1, wherein the first semiconductor layer is a metal oxide semiconductor layer being in direct contact with the gate insulating layer, the second semiconductor layer is a heavily doped amorphous silicon semiconductor layer being in direct contact with source and drain metal electrodes, and the first semiconductor layer and the second semiconductor layer form a double-layered semiconductor layer structure.

12. The manufacturing method according to claim 1, wherein the gate insulating layer has a thickness of 2000 to 5000 Å, and the gate insulating layer is made of a material selected from an oxide, a nitride, or an oxynitride.

13. The manufacturing method according to claim 1, wherein the first semiconductor layer is made of a material selected from an amorphous indium-gallium-zinc oxide a-IGZO, HIZO, IZO, a-InZnO, ZnaF, In2O3:Sn, In2O3:Mo, Cd2SnO4, ZnO:Al, TiO2:Nb, or Cd—Sn—O, and the first semiconductor layer is provided as a single layer or multiple layers.

14. The manufacturing method according to claim 1, wherein the source/drain metal layer is made of a material selected from Cr, W, Ti, Ta, Mo, or an alloy thereof, and the source/drain metal layer is provided as a single layer or multiple layers.

15. The manufacturing method according to claim 1, wherein the passivation layer has a thickness of 2000 to 5000 Å, the passivation layer is made of a material selected from an oxide, a nitride, or an oxynitride, and the passivation layer is provided as a single layer or multiple layers.

16. The manufacturing method according to claim 1, wherein the transparent conductive layer has a thickness of 300 to 1500 Å, and the transparent conductive layer is made of a material selected from an indium tin oxide ITO or an indium zinc oxide IZO.

17. The manufacturing method according to claim 1, wherein the gate electrode has a thickness of 500 to 4000 Å, and the gate electrode is made of a material selected from Cr, W, Ti, Ta, Mo, Al, Cu, or an alloy thereof.

18. The manufacturing method according to claim 1, wherein the array substrate comprises a base substrate, and, sequentially disposed on the base substrate, a gate electrode, a gate insulating layer, a first semiconductor layer, a second semiconductor layer, a source/drain layer, a passivation layer, and a pixel electrode, wherein the source/drain layer comprises a source electrode and a drain electrode, and a channel region is provided between the source electrode and the drain electrode;
the first semiconductor layer is a metal oxide semiconductor layer, and the second semiconductor layer is a heavily doped amorphous silicon semiconductor layer; a protective layer is provided in the channel region, and the protective layer is an oxide of silicon formed by performing an oxidation treatment on the second semiconductor layer; and
the passivation layer is provided with a conductive via hole, through which the pixel electrode communicates with the drain electrode.

19. The manufacturing method according to claim 2, wherein the first semiconductor layer is a metal oxide semiconductor layer, comprising an amorphous indium-gallium-zinc oxide a-IGZO.

20. The manufacturing method according to claim 2, wherein the second semiconductor layer is a heavily doped amorphous silicon semiconductor layer.
